(19) United States
(12) Patent Application Publication
(10) Pub. No.: US 2026/0360021 A1
(43) Pub. Date: Nov. 12, 2026

(54) METHOD FOR PROMOTING REPODUCIBILITY IN OCTREE CODING FOR POINT CLOUD COMPRESSION

(71) Applicant: InterDigital VC Holdings, Inc., Wilmington, DE (US)

(72) Inventors: Muhammad Asad Lodhi, Highland Park, NJ (US); Junghyun Ahn, New York, NY (US); Jiahao Pang, Plainsboro, NJ (US); Dong Tian, Boxborough, MA (US)

(21) Appl. No.: 19/200,146

(22) Filed: May 6, 2025

(51) Int. Cl. G06T 9/20; G06T 9/00; G06T 9/40

(52) U.S. Cl. CPC G06T 9/20; G06T 9/001; G06T 9/002; G06T 9/40

(57) ABSTRACT

Some embodiments of a method may include: obtaining an output of an occupancy probability estimation process; obtaining a quantization step size and a maximum tolerable error; quantizing the output according to the quantization step size; identifying risky and safe entries of the output; and applying a loss function to the risky and safe entries.

### INCORPORATION BY REFERENCE

The present application incorporates by reference in their entirety the following applications: U.S. Non-Provisional patent application Ser. No. 19/094,753, entitled “REPRODUCIBLE LEARNING-BASED POINT CLOUD CODING” and filed Mar. 28, 2025 (“'753 application”); U.S. Non-Provisional patent application Ser. No. 19/088,367, entitled “PROTECTION MASK CODING FOR REPRODUCIBLE LEARNING-BASED COMPRESSION” and filed Mar. 24, 2025 (“'367 application”); U.S. Non-Provisional patent application Ser. No. 19/098,620, entitled “METHOD FOR PROMOTING REPRODUCIBILITY IN HYPERPRIOR MODEL FOR POINT CLOUD CODING” and filed Apr. 2, 2025 (“'620 application”); International Patent Application Serial No. PCT/US2025/023951, entitled “REPRODUCIBLE LEARNING-BASED POINT CLOUD CODING” and filed Apr. 9, 2025 (“'951 application”); and U.S. Non-Provisional patent application Ser. No. 18/637,370, entitled “REPRODUCIBLE LEARNING-BASED POINT CLOUD CODING” and filed Apr. 16, 2024 (“'370 application”).

### BACKGROUND

The present application is related to point clouds.

### SUMMARY

An example method in accordance with some embodiments may include: obtaining an output of an occupancy probability estimation process; obtaining a quantization step size and a maximum tolerable error; quantizing the output according to the quantization step size; identifying risky and safe entries of the output; and applying a loss function to the risky and safe entries.

Some embodiments of the example method may further include training the occupancy probability estimation process.

For some embodiments of the example method, the training is done from scratch, and scratch is a neutral starting point.

For some embodiments of the example method, the occupancy probability estimation process was previously trained, and training the occupancy probability estimation process includes finetuning weights of the already-trained occupancy probability estimation process.

For some embodiments of the example method, identifying the risky and safe entries includes: determining quantization boundaries from the quantization step assuming uniform quantization; determining a distance between an entry and a respective closest quantization boundary of the entry; and indicating whether the entry falls within a threshold distance of the respective closest quantization boundary.

For some embodiments of the example method, wherein the threshold distance is ceₘₐₓ, wherein eₘₐₓ is the maximum tolerable error, wherein c is a constant, and wherein c is greater than or equal to 1.

For some embodiments of the example method, identifying the risky and safe entries further includes: identifying the risky entries as entries in which the distance is less than or equal to the value ceₘₐₓ; and identifying the safe entries as entries in which the distance is greater than the value ceₘₐₓ.

For some embodiments of the example method, identifying risky and safe entries includes: indicating the risky entries as entries inside a range around their respective quantization boundaries; and indicating the safe entries as entries outside the range around their respective quantization boundaries.

Some embodiments of the example method may further include: obtaining a safeguard bitstream; and extracting the quantization boundaries from the safeguard bitstream.

For some embodiments of the example method, applying the loss function includes applying the same penalty to the risky entries and the safe entries.

For some embodiments of the example method, applying the loss function includes: applying a first penalty to the safe entries, wherein the first penalty is zero; and applying a second penalty to the risky entries, wherein the first penalty is different than the second penalty.

For some embodiments of the example method, applying the loss function includes applying a penalty only to the risky entries.

For some embodiments of the example method, applying the loss function to the risky and safe entries includes applying a penalty to each of the risky entries based on how close the respective risky entry is to the corresponding quantization boundary.

For some embodiments of the example method, applying the loss function to the risky and safe entries includes applying a penalty to each of the risky entries based on a square of a distance between a predicted value corresponding to the respective risky entry and a center of a respective quantization bin.

For some embodiments of the example method, applying the loss function includes assigning a penalty to the entries based on an exponential of a distance between a predicted value for the entry and a center of a corresponding quantization bin center.

For some embodiments of the example method, the maximum tolerable error is set at run-time.

Some embodiments of the example method may further include: receiving a bitstream; and performing an arithmetic decode (AE) of the bitstream, wherein an AE output of the arithmetic decode is a reconstructed point cloud.

Some embodiments of the example method may further include obtaining a safeguard bitstream.

For some embodiments of the example method, quantizing the output includes performing a non-uniform quantization on the output.

An example apparatus in accordance with some embodiments may include: a processor; and a memory storing instructions operative, when executed by the processor, to cause the apparatus to: obtain an output of an occupancy probability estimation process; obtain a quantization step size and a maximum tolerable error; quantize the output according to the quantization step size; identify risky and safe entries of the output; and apply a loss function to the risky and safe entries.

### BRIEF DESCRIPTION OF THE DRAWINGS

The following detailed description will be better understood when read in conjunction with the appended drawings, in which there are shown examples of one or more of the multiple embodiments of the present application. It should be understood, however, that the embodiments described herein are not limited to the precise arrangements and instrumentalities shown in the drawings. In the drawings:

FIG. 1 is a system diagram illustrating an example set of interfaces for a system according to some embodiments.

FIG. 2 is a flowchart illustrating an example encoding process according to some embodiments.

FIG. 3 is a flowchart illustrating an example decoding process according to some embodiments.

FIG. 4 is a schematic illustration showing an example quantization mapping process according to some embodiments.

FIG. 5 is a process diagram illustrating an example deep octree coding process according to some embodiments.

FIG. 6 is a process diagram illustrating an example reproducible deep octree coding process according to some embodiments.

FIG. 7 is a graph showing a first example loss function according to some embodiments.

FIG. 8 is a graph showing a second example loss function according to some embodiments.

FIG. 9 is a graph showing a third example loss function according to some embodiments.

FIG. 10 is a flowchart illustrating an example reproducible deep octree coding process according to some embodiments.

The entities, connections, arrangements, and the like that are depicted in—and described in connection with—the various figures are presented by way of example and not by way of limitation. As such, any and all statements or other indications as to what a particular figure “depicts,” what a particular element or entity in a particular figure “is” or “has,” and any and all similar statements—that may in isolation and out of context be read as absolute and therefore limiting—may only properly be read as being constructively preceded by a clause such as “In at least one embodiment, . . . .” For brevity and clarity of presentation, this implied leading clause is not repeated ad nauseum in the detailed description.

### DETAILED DESCRIPTION

In describing the various embodiments of the present application, certain terminology is used herein for convenience only and should not be considered as limiting such embodiments. In the drawings, the same reference numerals are employed for designating the same elements throughout the several figures and the present description.

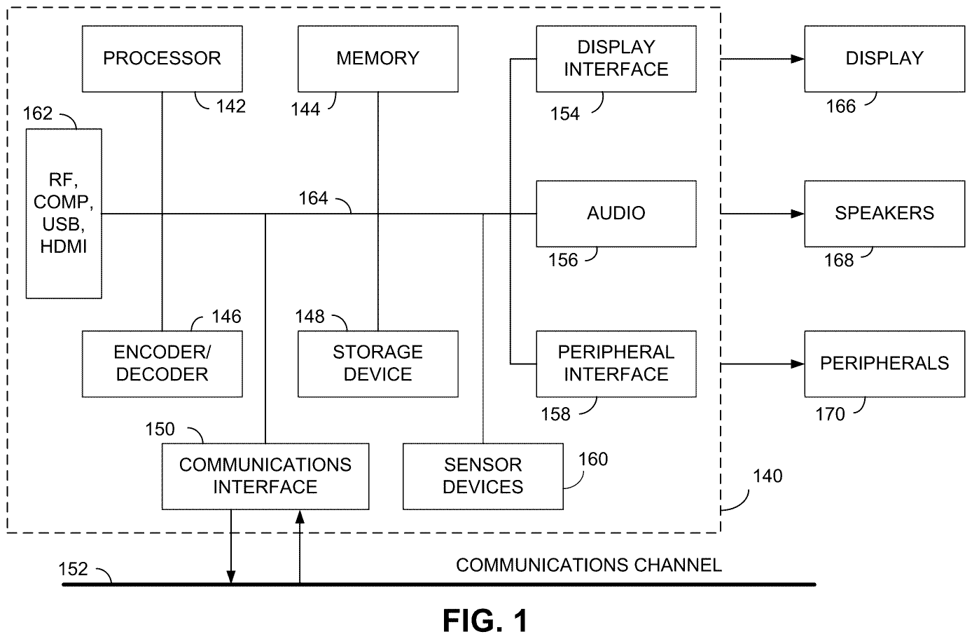

FIG. 1 is a system diagram illustrating an example set of interfaces for a system according to some embodiments. An extended reality display device, together with its control electronics, may be implemented using a system such as the system of FIG. 1. System 140 can be embodied as a device including the various components described below and is configured to perform one or more of the aspects described in this document. Examples of such devices, include, but are not limited to, various electronic devices such as personal computers, laptop computers, smartphones, tablet computers, digital multimedia set top boxes, digital television receivers, personal video recording systems, connected home appliances, and servers. Elements of system 140, singly or in combination, can be embodied in a single integrated circuit (IC), multiple ICs, and/or discrete components. For example, in at least one embodiment, the processing and encoder/decoder elements of system 140 are distributed across multiple ICs and/or discrete components. In various embodiments, the system 140 is communicatively coupled to one or more other systems, or other electronic devices, via, for example, a communications bus or through dedicated input and/or output ports. In various embodiments, the system 140 is configured to implement one or more of the aspects described in this document.

The system 140 includes at least one processor 142 configured to execute instructions loaded therein for implementing, for example, the various aspects described in this document. Processor 142 may include embedded memory, input output interface, and various other circuitries as known in the art. The system 140 includes at least one memory 144 (e.g., a volatile memory device, and/or a non-volatile memory device). System 140 may include a storage device 148, which can include non-volatile memory and/or volatile memory, including, but not limited to, Electrically Erasable Programmable Read-Only Memory (EEPROM), Read-Only Memory (ROM), Programmable Read-Only Memory (PROM), Random Access Memory (RAM), Dynamic Random Access Memory (DRAM), Static Random Access Memory (SRAM), flash, magnetic disk drive, and/or optical disk drive. The storage device 148 can include an internal storage device, an attached storage device (including detachable and non-detachable storage devices), and/or a network accessible storage device, as non-limiting examples.

System 140 includes an encoder/decoder module 146 configured, for example, to process data to provide an encoded video or decoded video, and the encoder/decoder module 146 can include its own processor and memory. The encoder/decoder module 146 represents module(s) that can be included in a device to perform the encoding and/or decoding functions. As is known, a device can include one or both of the encoding and decoding modules. Additionally, encoder/decoder module 146 can be implemented as a separate element of system 140 or can be incorporated within processor 142 as a combination of hardware and software as known to those skilled in the art.

Program code to be loaded onto processor 142 or encoder/decoder 146 to perform the various aspects described in this document can be stored in storage device 148 and subsequently loaded onto memory 144 for execution by processor 142. In accordance with various embodiments, one or more of processor 142, memory 144, storage device 148, and encoder/decoder module 146 can store one or more of various items during the performance of the processes described in this document. Such stored items can include, but are not limited to, the input video, the decoded video or portions of the decoded video, the bitstream, matrices, variables, and intermediate or final results from the processing of equations, formulas, operations, and operational logic.

In some embodiments, memory inside of the processor 142 and/or the encoder/decoder module 146 is used to store instructions and to provide working memory for processing that is needed during encoding or decoding. In other embodiments, however, a memory external to the processing device (for example, the processing device can be either the processor 142 or the encoder/decoder module 142) is used for one or more of these functions. The external memory can be the memory 144 and/or the storage device 148, for example, a dynamic volatile memory and/or a non-volatile flash memory. In several embodiments, an external non-volatile flash memory is used to store the operating system of, for example, a television. In at least one embodiment, a fast external dynamic volatile memory such as a RAM is used as working memory for video coding and decoding operations, such as for MPEG-2 (MPEG refers to the Moving Picture Experts Group, MPEG-2 is also referred to as ISO/IEC 13818, and 13818-1 is also known as H.222, and 13818-2 is also known as H.262), HEVC (HEVC refers to High Efficiency Video Coding, also known as H.265 and MPEG-H Part 2), or VVC (Versatile Video Coding, a new standard being developed by JVET, the Joint Video Experts Team).

The input to the elements of system 140 can be provided through various input devices as indicated in block 162. Such input devices include, but are not limited to, (i) a radio frequency (RF) portion that receives an RF signal transmitted, for example, over the air by a broadcaster, (ii) a Component (COMP) input terminal (or a set of COMP input terminals), (iii) a Universal Serial Bus (USB) input terminal, and/or (iv) a High Definition Multimedia Interface (HDMI) input terminal. Other examples, not shown in FIG. 1, include composite video.

In various embodiments, the input devices of block 162 have associated respective input processing elements as known in the art. For example, the RF portion can be associated with elements suitable for (i) selecting a desired frequency (also referred to as selecting a signal, or band-limiting a signal to a band of frequencies), (ii) downconverting the selected signal, (iii) band-limiting again to a narrower band of frequencies to select (for example) a signal frequency band which can be referred to as a channel in certain embodiments, (iv) demodulating the downconverted and band-limited signal, (v) performing error correction, and (vi) demultiplexing to select the desired stream of data packets. The RF portion of various embodiments includes one or more elements to perform these functions, for example, frequency selectors, signal selectors, band-limiters, channel selectors, filters, downconverters, demodulators, error correctors, and demultiplexers. The RF portion can include a tuner that performs various of these functions, including, for example, downconverting the received signal to a lower frequency (for example, an intermediate frequency or a near-baseband frequency) or to baseband. In one set-top box embodiment, the RF portion and its associated input processing element receives an RF signal transmitted over a wired (for example, cable) medium, and performs frequency selection by filtering, downconverting, and filtering again to a desired frequency band. Various embodiments rearrange the order of the above-described (and other) elements, remove some of these elements, and/or add other elements performing similar or different functions. Adding elements can include inserting elements in between existing elements, such as, for example, inserting amplifiers and an analog-to-digital converter. In various embodiments, the RF portion includes an antenna.

Additionally, the USB and/or HDMI terminals can include respective interface processors for connecting system 140 to other electronic devices across USB and/or HDMI connections. It is to be understood that various aspects of input processing, for example, Reed-Solomon error correction, can be implemented, for example, within a separate input processing IC or within processor 142 as necessary. Similarly, aspects of USB or HDMI interface processing can be implemented within separate interface ICs or within processor 142 as necessary. The demodulated, error corrected, and demultiplexed stream is provided to various processing elements, including, for example, processor 142, and encoder/decoder 146 operating in combination with the memory and storage elements to process the datastream as necessary for presentation on an output device.

Various elements of system 140 can be provided within an integrated housing, Within the integrated housing, the various elements can be interconnected and transmit data therebetween using suitable connection arrangement 164, for example, an internal bus as known in the art, including the Inter-IC (12C) bus, wiring, and printed circuit boards.

The system 140 includes communication interface 150 that enables communication with other devices via communication channel 152. The communication interface 150 can include, but is not limited to, a transceiver configured to transmit and to receive data over communication channel 152. The communication interface 150 can include, but is not limited to, a modem or network card and the communication channel 152 can be implemented, for example, within a wired and/or a wireless medium.

Data is streamed, or otherwise provided, to the system 140, in various embodiments, using a wireless network such as a Wi-Fi network, for example IEEE 802.11 (IEEE refers to the Institute of Electrical and Electronics Engineers). The Wi-Fi signal of these embodiments is received over the communications channel 152 and the communications interface 150 which are adapted for Wi-Fi communications. The communications channel 152 of these embodiments is typically connected to an access point or router that provides access to external networks including the Internet for allowing streaming applications and other over-the-top communications. Other embodiments provide streamed data to the system 140 using a set-top box that delivers the data over the HDMI connection of the input block 162. Still other embodiments provide streamed data to the system 140 using the RF connection of the input block 162. As indicated above, various embodiments provide data in a non-streaming manner. Additionally, various embodiments use wireless networks other than Wi-Fi, for example a cellular network or a Bluetooth network.

The system 140 can provide an output signal to various output devices, including a display 166, speakers 168, and other peripheral devices 170. The display 166 of various embodiments includes one or more of, for example, a touchscreen display, an organic light-emitting diode (OLED) display, a curved display, and/or a foldable display. The display 166 can be for a television, a tablet, a laptop, a cell phone (mobile phone), or other device. The display 166 can also be integrated with other components (for example, as in a smart phone), or separate (for example, an external monitor for a laptop). The other peripheral devices 170 include, in various examples of embodiments, one or more of a stand-alone digital video disc (or digital versatile disc) (DVR, for both terms), a disk player, a stereo system, and/or a lighting system. Various embodiments use one or more peripheral devices 170 that provide a function based on the output of the system 140. For example, a disk player performs the function of playing the output of the system 140.

In various embodiments, control signals are communicated between the system 140 and the display 166, speakers 168, or other peripheral devices 170 using signaling such as AV.Link, Consumer Electronics Control (CEC), or other communications protocols that enable device-to-device control with or without user intervention. The output devices can be communicatively coupled to system 140 via dedicated connections through respective interfaces 154, 156, and 158. Alternatively, the output devices can be connected to system 140 using the communications channel 152 via the communications interface 150. The display 166 and speakers 168 can be integrated in a single unit with the other components of system 140 in an electronic device such as, for example, a television. In various embodiments, the display interface 154 includes a display driver, such as, for example, a timing controller (T Con) chip.

The display 166 and speaker 168 can alternatively be separate from one or more of the other components, for example, if the RF portion of input 162 is part of a separate set-top box. In various embodiments in which the display 166 and speakers 168 are external components, the output signal can be provided via dedicated output connections, including, for example, HDMI ports, USB ports, or COMP outputs.

The system 140 may include one or more sensor devices 160. Examples of sensor devices that may be used include one or more GPS sensors, gyroscopic sensors, accelerometers, light sensors, cameras, depth cameras, microphones, and/or magnetometers. Such sensors may be used to determine information such as user's position and orientation. Where the system 140 is used as the control module for an extended reality display (such as control modules), the user's position and orientation may be used in determining how to render image data such that the user perceives the correct portion of a virtual object or virtual scene from the correct point of view. In the case of head-mounted display devices, the position and orientation of the device itself may be used to determine the position and orientation of the user for the purpose of rendering virtual content. In the case of other display devices, such as a phone, a tablet, a computer monitor, or a television, other inputs may be used to determine the position and orientation of the user for the purpose of rendering content. For example, a user may select and/or adjust a desired viewpoint and/or viewing direction with the use of a touch screen, keypad or keyboard, trackball, joystick, or other input. Where the display device has sensors such as accelerometers and/or gyroscopes, the viewpoint and orientation used for the purpose of rendering content may be selected and/or adjusted based on motion of the display device.

The embodiments can be carried out by computer software implemented by the processor 142 or by hardware, or by a combination of hardware and software. As a non-limiting example, the embodiments can be implemented by one or more integrated circuits. The memory 144 can be of any type appropriate to the technical environment and can be implemented using any appropriate data storage technology, such as optical memory devices, magnetic memory devices, semiconductor-based memory devices, fixed memory, and removable memory, as non-limiting examples. The processor 142 can be of any type appropriate to the technical environment, and can encompass one or more of microprocessors, general purpose computers, special purpose computers, and processors based on a multi-core architecture, as non-limiting examples.

A User Equipment (UE) may correspond to any eXtended Reality (XR) device/node which may come in variety of form factors. Typical UE (e.g., XR UE) may include, but not limited to the following: Head Mounted Displays (HMD), optical see-through glasses and video see-through HMDs for Augmented Reality (AR) and Mixed Reality (MR), mobile devices with positional tracking and camera, wearables etc. In addition to the above, several different types of XR UE may be envisioned based on XR device functions for e.g., as display, camera, sensors, sensor processing, wireless connectivity, XR/Media processing, and power supply, to be provided by one or more devices, wearables, actuators, controllers and/or accessories. One or more device/nodes/UEs may be grouped into a collaborative XR group for supporting any of XR applications/experience/services.

### Point Cloud Data Format

The field of point cloud compression and processing aims to develop tools for compression, analysis, interpolation, representation, and understanding of input signals, such as point clouds.

Point cloud data is a universal data format used across several business domains from autonomous driving, robotics, AR/VR, civil engineering, computer graphics, to the animation/movie industry. 3D LiDAR sensors have been deployed in self-driving cars, and affordable LiDAR sensors are released from Velodyne Velabit, Apple iPad Pro 2020, and Intel RealSense LiDAR camera L515. With advances in sensing technologies, 3D point cloud data becomes more practical than ever.

Point cloud data is also believed to consume a large portion of network traffic, e.g., among connected cars over 5G network, and immersive communications (VR/AR). Efficient representation formats may be necessary for point cloud understanding and communication. In particular, raw point cloud data may be organized and processed for the purposes of world modeling and sensing. Compression of raw point clouds may be used when storage and transmission of the data are used in related scenarios.

Furthermore, point clouds may represent a sequential scan of the same scene, which contains multiple moving objects. They are called dynamic point clouds, while static point clouds may be captured from a static scene or static objects. Dynamic point clouds are typically organized into frames, with different frames being captured at different times. Dynamic point clouds may require the processing and compression to be handled in real-time or with low delay.

Each point of the point cloud may be represented by at least a 3D position (x, y, z). The set of 3D positions illustrates the geometry of the object/scene from which the point cloud is captured. Additionally, each point of the point cloud may be associated with some attributes, depending on the application. For example, for VR/AR/Gaming, the attribute may include color (r, g, b), and for LiDAR, the attribute may include reflectance.

### Point Cloud Data Use Cases

The automotive industry and autonomous cars are domains in which point clouds may be used. Autonomous cars are able to “probe” their environment to make good driving decisions based on the reality of their immediate surroundings. Typical sensors, like LiDARs, produce (dynamic) point clouds that are used by the perception engine. These point clouds are not intended to be viewed by human eyes, and they are typically sparse, not necessarily colored, and dynamic with a high frequency of capture. They may have other attributes, like the reflectance ratio provided by the LiDAR because this attribute may be indicative of the material of the sensed object, and this attribute may be used in making a decision.

Virtual Reality (VR) and immersive worlds have become a hot topic and are foreseen by many as the future of 2D flat video. The viewer is immersed in an environment all around the viewer, while in standard TV, the viewer may look only at the virtual world in front of the viewer. There are several gradations in the immersivity depending on the freedom of the viewer in the environment. Point clouds are a good format candidate to distribute VR worlds. They may be static or dynamic and are typically of average size, with, e.g., no more than millions of points at a time.

Point clouds also may be used for various purposes, such as cultural heritage/buildings, in which objects, like statues or buildings, are scanned in 3D to share the spatial configuration of the object without sending or visiting the statues or buildings. Also, point clouds offer a way to ensure preservation of knowledge of the object in case the original object, for instance, is destroyed by an earthquake. Such point clouds are typically static, colored, and huge.

Another use case is in topography and cartography in which, when using 3D representations, maps are not limited to the plane and may include the relief. Google Maps is a good example of 3D maps but is understood to use meshes instead of point clouds. Nevertheless, point clouds may be a suitable data format for 3D maps, and such point clouds are typically static, colored, and huge.

World modeling and sensing via point clouds may be a technology that allows machines to gain knowledge about the 3D world around them, which may be used by the applications discussed above.

3D point cloud data includes discrete samples of the surfaces of objects or scenes. A huge number of points may be used to fully represent the real world with point samples. For instance, a typical VR immersive scene may contain millions of points, while point clouds typically contain hundreds of millions of points. Therefore, the processing of such large-scale point clouds may be computationally expensive, especially for consumer devices, such as smartphones, tablets, and automotive navigation systems, that have limited computational power.

The first step for processing or inference on a point cloud is to have efficient storage methodologies. To store and process the input point cloud with affordable computational cost, the point cloud may be down-sampled first, in which the down-sampled point cloud summarizes the geometry of the input point cloud while having much fewer points. The down-sampled point cloud may be inputted into a machine task for further processing. However, further reduction in storage space may be achieved by converting the raw point cloud data (original or down-sampled) into a bitstream through entropy coding techniques for lossless compression.

In addition to lossless coding, many scenarios may use lossy coding for significantly improved compression ratios while maintaining the induced distortion under certain quality levels. To achieve a less lossy coding, an efficient point feature extractor may be used to improve the accuracy of the reconstruction within the given resource budget.

### Learning-Based Point Cloud Compression

Since point cloud data is composed of two components: geometry information and attribute information, the compression of point clouds may be classified into two categories: geometry coding and attribute coding.

Examples of existing learning-based point cloud geometry compression techniques include deep octree coding and end-to-end feature-based geometry coding. With deep octree coding, neural network-based models are utilized to estimate the occupancy probabilities. Such estimated probabilities may be used to help the arithmetic coder to encode or decode a binary flag indicating whether a child octree voxel is occupied or empty.

Inference reproducibility is a well-known problem. Neural network models may produce results with minor differences when run on different hardware or software platforms or when run multiple times. When these neural network models are used for entropy encoding and decoding, a slightly different output may be a severe problem for the entropy encoder and decoder. This issue will not only output a different point cloud but may crash a decoding process. An additional protection bitstream for risky entries may be produced to ensure reproducibility in point cloud compression. Alternatively, a training approach may be used to promote reproducibility in learning-based point cloud compression and reduce the size of the protection bitstream.

Some technologies exist to help relieve the reproducibility challenge of a neural network. Two technologies are briefly described herein. However, unless the hardware and software platform are strictly aligned, these techniques are understood to lack full reproducibility.

This application provides, for some embodiments, a way to promote reproducibility in the deep octree coding model within learning-based point cloud compression methods, across different platforms. The method imposes an additional loss during the training to promote predicted occupancy probabilities that lie close to the centers of the quantization bins. Furthermore, this application provides, for some embodiments, a training method that may be used to promote reproducibility in learning-based point cloud compression in the context of hyperprior model.

### Quantization

Quantization, which is discussed in Gholami, A., et al., A Survey of Quantization Methods for Efficient Neural Network Inference, IN Low-POWER COMPUTER VISION 291-326, Chapman and Hall/CRC (2022), reduces the computational and memory costs of running inference by representing numerical values (weights and activations) using low-precision data types (e.g., 8-bit integers) instead of traditional 32-bit floating-point data types.

By using fixed-point representations, quantization also promotes more consistent behavior across different hardware and software environments. Quantization mitigates the impact of floating-point rounding errors, leading to more predictable results during inference. Quantized models are lightweight and suitable for deployment on resource-constrained devices, like mobile phones and edge devices. However, quantization still cannot fully guarantee reproducibility—which may be critical for learning-based compression.

### Activation Functions

Deep learning models may use activation functions, like Rectified Linear Units (ReLU), which are discussed in Rasamoelina, Andrinandrasana David, et al., A Review of Activation Function for Artificial Neural Network, IN 2020 IEEE 18TH WORLD SYMPOSIUM ON APPLIED MACHINE INTELLIGENCE AND INFORMATICS (SAMI) 281-286, IEEE (2020). ReLU exacerbates irreproducibility due to its non-smooth derivative behavior.

Smooth activation functions have continuous derivatives across their entire domain, unlike ReLU. Examples include sigmoid, tanh, and swish. Smooth ReLU (SmeLU) activation function may balance reproducibility and accuracy without the complexity of other solutions. Again, there is no guarantee that activation brings fully reproducible results but may only mitigate the issue. However, for learning-based compression, reproducibility may be indispensable.

### Rule-Based Quantization

Some details about rule-based quantization are provided below. An AI-based module M is assumed to be deployed to compute a scalar variable per sample. The sample is a point in point cloud compression. For a hyperprior model, the variable may be Gaussian distribution parameters, e.g., mean and variance numbers.

Let vₓ be the variable, in which x is the sample. Typically, vₓ is a floating-point number computed by an AI-based model. Though some AI-based processes may use integers as neural network weights, the output may still not reproducible. Without losing generality, the variable vₓ is assumed to be a floating-point number, which suffers a reproducibility problem across different platforms.

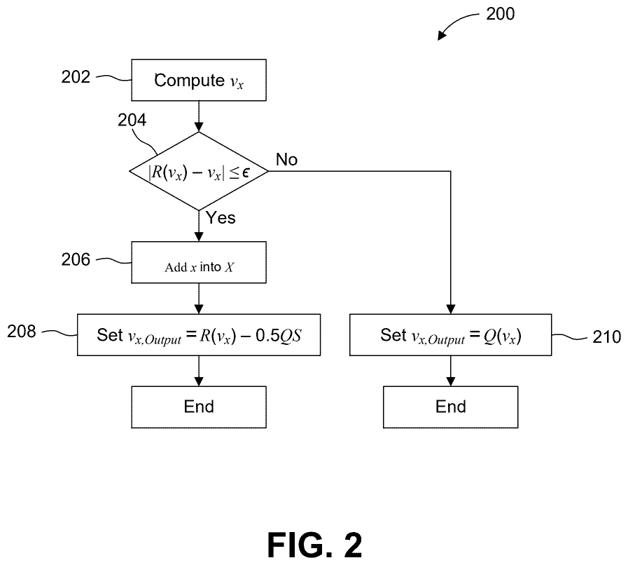

FIG. 2 is a flowchart illustrating an example encoding process according to some embodiments. For the encoder process 200 of FIG. 2, the variable vₓ is computed 202. The absolute distance of the variable vₓ from its rounded position R(vₓ) is checked 204. If the error is larger than or equal to a certain threshold E, the variable is assumed to be in a “safe” range. The output is set 210 to its quantized value v_{x,output}=Q(vₓ) and the encoder process 200 ends.

If the error is less than a certain threshold E, the current point x is added 206 to set X (which is signaled to the decoder), and the variable vₓ is set 208 to v_{x,ouput}=R(vₓ)−0.5 QS. In other words, the variable vₓ is shifted to the left of the rounded value by half of the quantization step. Then, the encoder process 200 ends.

The “left-preferred method” shown in FIG. 2 may appear less accurate because some values on the right side of the rounded value are quantized to a value not closest to the variable. However, the process 200 avoids signaling a flag fₓ.

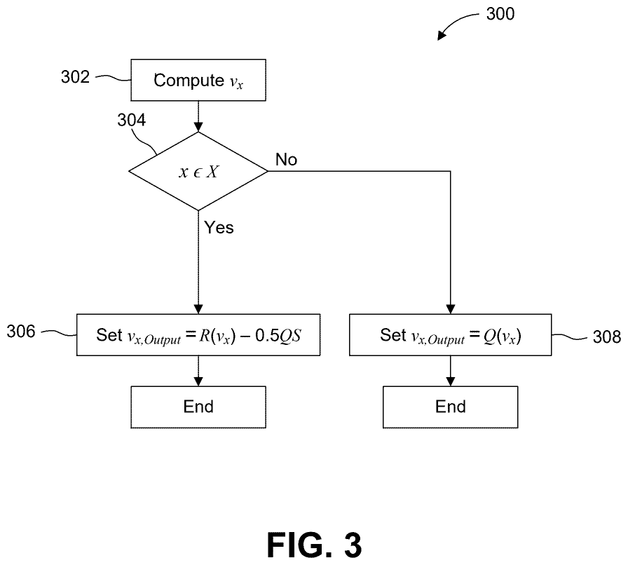

FIG. 3 is a flowchart illustrating an example decoding process according to some embodiments. For the decoder process 300 of FIG. 3, the variable vₓ is computed 302 and a determination 304 is made on whether a current point x belongs to the set X. If the current point x does not belong to the set X, the output is set 308 to its quantized value v_{x,output}=Q (vₓ), and the decoder process 300 ends. Otherwise, the output is set 306 to v_{x,output}=R(vₓ)−0.5 QS, and the decoder process 300 ends.

Similar to the “left-preferred method”, a “right-preferred” quantization may be performed. If the encoder detects that the current point is in the risky range, the output is set to be v_{x,output}=R(vₓ)+0.5 for the “right-preferred method”.

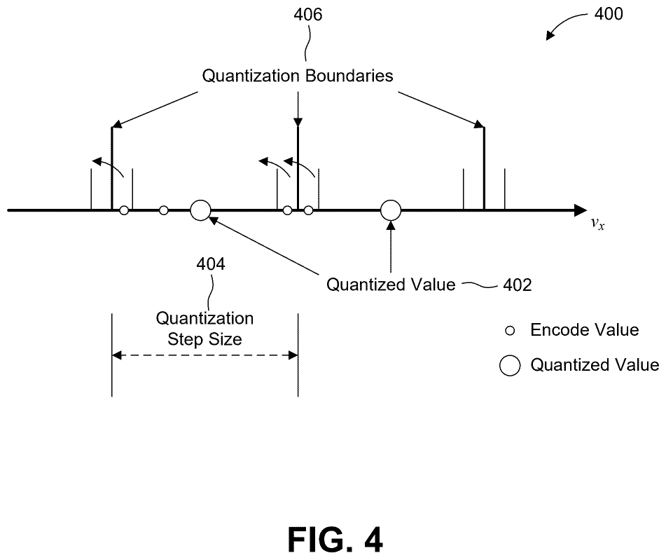

FIG. 4 is a schematic illustration showing an example quantization mapping process according to some embodiments. The process 400 shows several quantization boundaries 406 with quantized values 402 located at the halfway point between each respective set of quantization boundaries 406. Each quantization boundary 406 is separated by a quantization step size 404. FIG. 4 shows multiple scenarios in which a raw encoder value is shifted to the left.

### Deep Octree Coding

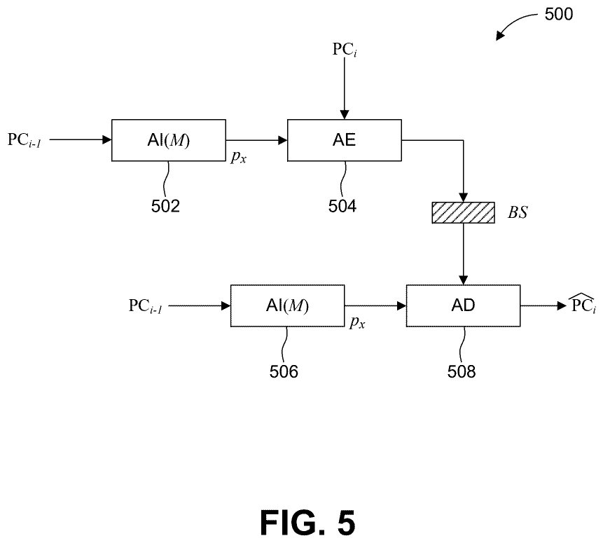

FIG. 5 is a process diagram illustrating an example deep octree coding process according to some embodiments. The coding of a point cloud may be done via the coding of its octree decomposition structure. For some embodiments, the empty/occupancy flag is coded for each child voxel in the octree structure.

As shown in the deep octree coding process 500 of FIG. 5, an AI model M (AI(M) blocks 502, 506) is used to predict the probability pₓ of a child voxel to be occupied. This model M is typically run on both encoder and decoder. The probability is used to guide the entropy coding via an arithmetic encoder (AE) block 504 and to guide the entropy decoding via the arithmetic decoder (AD) block 508 in FIG. 5. In this case, any mismatch in the probability value pₓ between the encoder and decoder may lead to a completely wrong decoding of an octree voxel. This issue is a serious error that will bring very poor point cloud reconstruction quality.

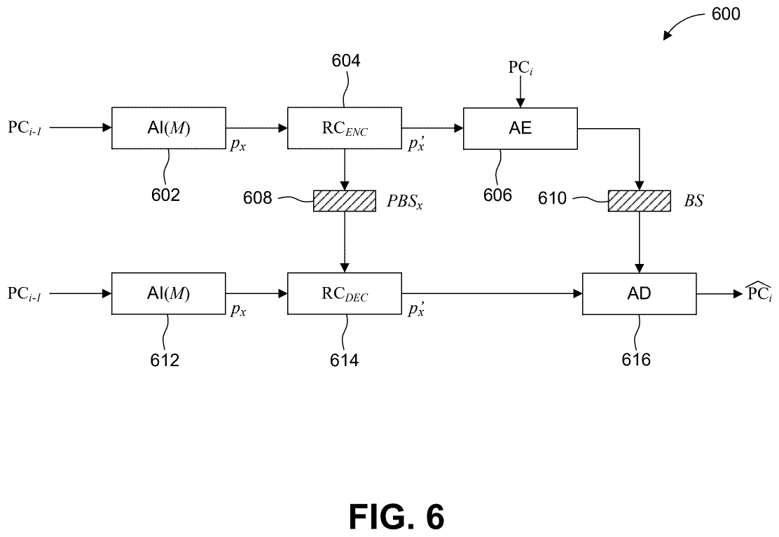

FIG. 6 is a process diagram illustrating an example reproducible deep octree coding process according to some embodiments. Some embodiments presented above may be used in deep octree coding. The probability pₓ may be treated as vₓ. This treatment leads to a modified encoding/decoding process 600 shown in FIG. 6. The “RC_{ENC}” block 604 and the “RC_{DEC}” block 614 are introduced in the encoder and decoder, respectively.

Use of an “RC_{ENC}” block 604 and an “RC_{DEC}” block 614 may follow one of the embodiments described earlier. The updated probability p′ₓ will be exactly matched between encoder and decoder. The newly generated safeguard bitstream 608 is labeled as PBSₓ for each point. Also, the output the arithmetic encoder (AE) 606 is outputted as a bitstream (BS) 610, which is inputted into the arithmetic decoder (AD) 616.

An AI model [symbol] (AI(M) blocks 602, 612) is used to predict the probability pₓ of a child voxel to be occupied. The probability is used by the “RC_{ENC}” block 604 to guide the entropy coding via an arithmetic encoder (AE) block 606. The probability is used by the “RC_{DEC}” block 614 to guide the entropy decoding via the arithmetic decoder (AD) block 616.

### Training Method

The goal of this application is to promote reproducibility in the output of the AI model [symbol] . Without any constraint during the training, the predicted values are equally likely to fall within the appropriate range for a predicted variable. In other words, when quantization is performed, the values are distributed uniformly within the quantization bin, with the probability of encountering risky entries being 2ϵ/q, in which ϵ is the error threshold and q is the size of the quantization bin.

To promote reproducibility, this application seeks to reduce the probability of predicted values falling in the risky range. This goal may be achieved by means of an additional loss in the finetuning stage. The additional loss penalizes the output entries of the AI model [symbol] according to their distances from the centers of the learned quantization bins. A higher penalty is imposed on entries farther away from the centers of the learned quantization bins. This methodology reduces the likelihood of entries falling into the risky zone, which leads to a smaller protection bitstream during inference.

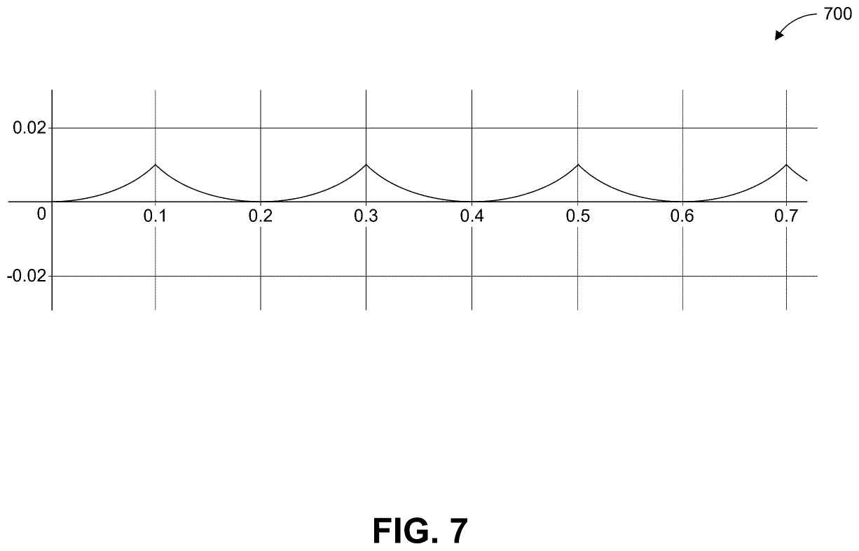

FIGS. 7-9 provide a few examples of the additional loss imposed during the finetuning stage. For the examples shown in FIGS. 7-9, the loss function is depicted for uniform quantization centers at multiples of 0.2.

FIG. 7 is a graph showing a first example loss function according to some embodiments. In some embodiments, the loss function penalizes the squared distance between a predicted value and the center of its corresponding quantization bin. The graph 700 of FIG. 7 shows this loss as Eq. 1:

l=∥x−cₓ∥² (1)

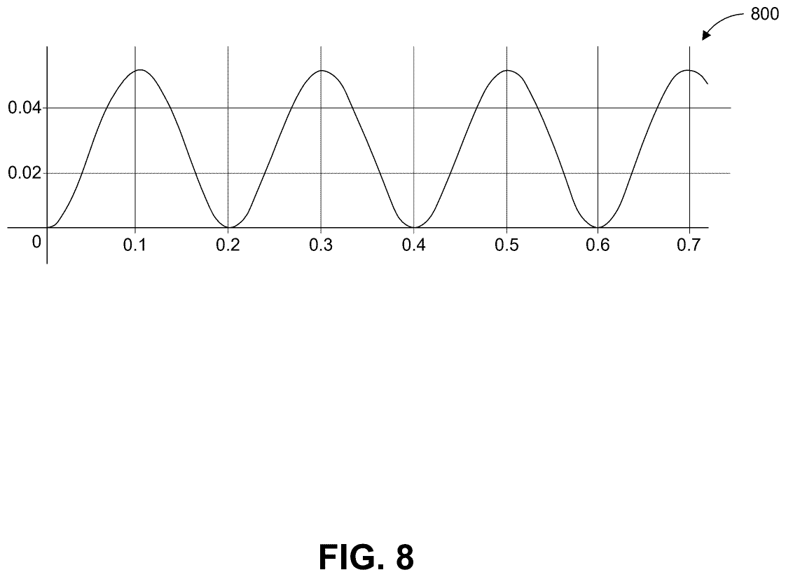

FIG. 8 is a graph showing a second example loss function according to some embodiments. In some embodiments, the loss function penalizes the exponential of the squared distance between a predicted value and the center of its corresponding quantization bin, which is Eq. 2:

l=exp(−∥x−cₓ∥²)−exp(−∥0.5∥²) (2)

FIG. 8 shows a graph 800 of the loss function of Eq. 2.

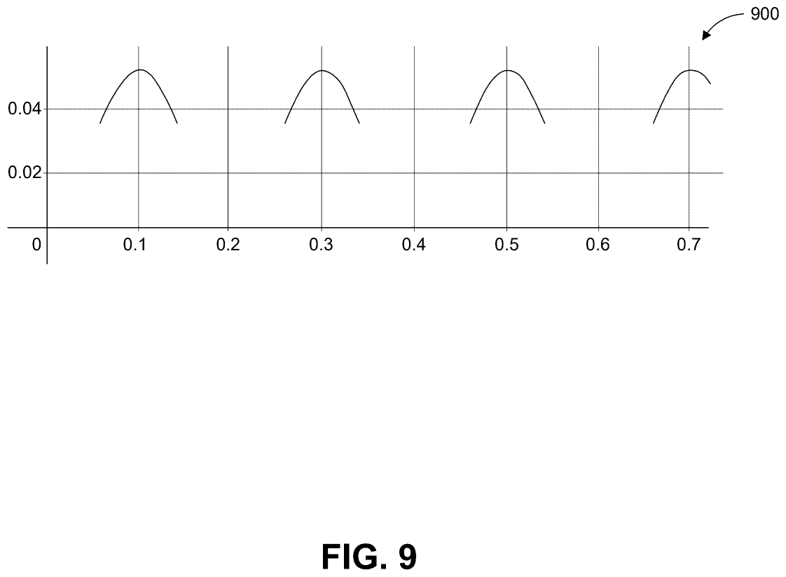

FIG. 9 is a graph showing a third example loss function according to some embodiments. In some embodiments, the loss function penalizes the exponential of the squared distance between a predicted value and the center of its corresponding quantization bin, as shown in Eq. 3:

l=exp(−∥x−cₓ∥)−exp(−∥0.5∥) (3)

For some embodiments, a squared loss may be used with l′=l².

For some embodiments, the loss is a piece-wise function that is imposed only on entries a certain distance away from bin centers. The loss may be as shown in Eq.4:

$${l}^{′} = w ⊙ l with \{ \begin{matrix}w = 1 & for ‖ x - {c}_{x} ‖ > ϵ \\ w = 0 & otherwise\end{matrix} \qquad ( 4 )$$

In effect, the loss function of Eq. 4 penalizes entries close to bin boundaries while neglecting entries close to bin centers.

For some embodiments, a loss function may produce a zero value at bin centers and a non-zero value at a bin boundary, increasing monotonically.

To include the additional loss in training, the quantization boundaries associated with the chosen quantization step size and an empirically determined maximum tolerable error are obtained. Then, the output is quantized, followed by a determination of the risky and safe entries by calculating their distance from the closest quantization boundary. Finally, the (appropriate) loss function is applied to the risky and safe entries.

Compatibility with Other Technologies

Since smaller E may reduce the overhead, quantizing neural network weights as shown above may be used to decrease the potential maximum error (max_err) so that a smaller E may be used without risks. For different target GPUs, a safeguard bitstream may be generated respectively. When a target GPU is known, the size of the safeguard bitstream may be reduced by selecting the same or a similar GPU for encoding.

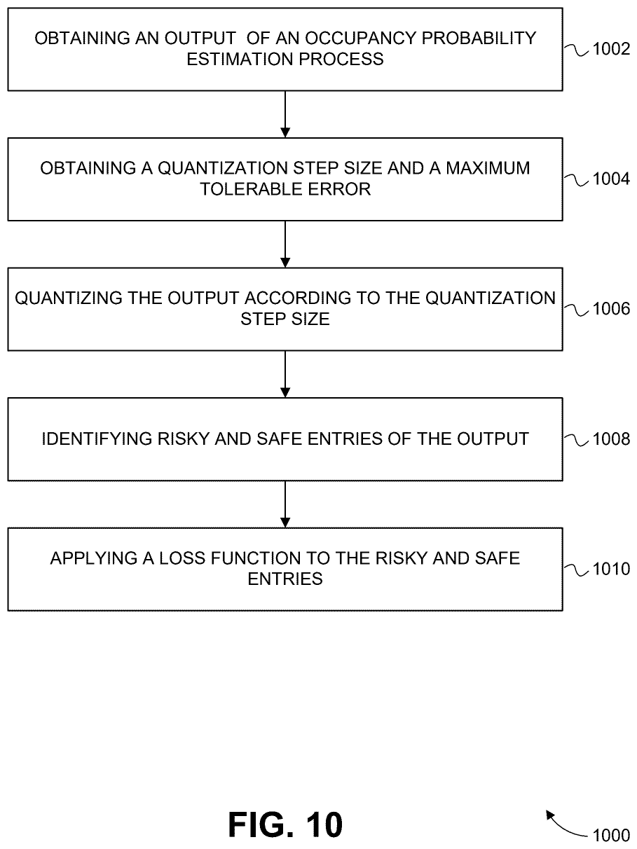

FIG. 10 is a flowchart illustrating an example reproducible deep octree coding process according to some embodiments. For some embodiments, an example process 1000 may include obtaining 1002 an output of an occupancy probability estimation process. For some embodiments, the example process 1000 may further include obtaining 1004 a quantization step size and a maximum tolerable error. For some embodiments, the example process 1000 may further include quantizing 1006 the output according to the quantization step size. For some embodiments, the example process 1000 may further include identifying 1008 risky and safe entries of the output. For some embodiments, the example process 1000 may further include applying 1010 a loss function to the risky and safe entries.

An example apparatus in accordance with some embodiments may include at least one processor configured to perform any one of the methods described within this application. An example apparatus in accordance with some embodiments may include a computer-readable medium storing instructions for causing one or more processors to perform any one of the methods described within this application. An example apparatus in accordance with some embodiments may include at least one processor and at least one non-transitory computer-readable medium storing instructions for causing the at least one processor to perform any one of the methods described within this application. An example signal in accordance with some embodiments may include a bitstream generated according to any one of the methods described within this application.

While the methods and systems in accordance with some embodiments are generally discussed in context of extended reality (XR), some embodiments may be applied to any XR contexts such as, e.g., virtual reality (VR)/mixed reality (MR)/augmented reality (AR) contexts. Also, although the term “head mounted display (HMD)” is used herein in accordance with some embodiments, some embodiments may be applied to a wearable device (which may or may not be attached to the head) capable of, e.g., XR, VR, AR, and/or MR for some embodiments.

An example method in accordance with some embodiments may include: obtaining an output of an occupancy probability estimation process; obtaining a quantization step size and a maximum tolerable error; quantizing the output according to the quantization step size; identifying risky and safe entries of the output; and applying a loss function to the risky and safe entries.

Some embodiments of the example method may further include training the occupancy probability estimation process.

For some embodiments of the example method, the training is done from scratch, and scratch is a neutral starting point.

For some embodiments of the example method, the occupancy probability estimation process was previously trained, and training the occupancy probability estimation process includes finetuning weights of the already-trained occupancy probability estimation process.

For some embodiments of the example method, identifying the risky and safe entries includes: determining quantization boundaries from the quantization step assuming uniform quantization; determining a distance between an entry and a respective closest quantization boundary of the entry; and indicating whether the entry falls within a threshold distance of the respective closest quantization boundary.

For some embodiments of the example method, wherein the threshold distance is ceₘₐₓ, wherein eₘₐₓ is the maximum tolerable error, wherein c is a constant, and wherein c is greater than or equal to 1.

For some embodiments of the example method, identifying the risky and safe entries further includes: identifying the risky entries as entries in which the distance is less than or equal to the value ceₘₐₓ; and identifying the safe entries as entries in which the distance is greater than the value ceₘₐₓ.

For some embodiments of the example method, identifying risky and safe entries includes: indicating the risky entries as entries inside a range around their respective quantization boundaries; and indicating the safe entries as entries outside the range around their respective quantization boundaries.

Some embodiments of the example method may further include: obtaining a safeguard bitstream; and extracting the quantization boundaries from the safeguard bitstream.

For some embodiments of the example method, applying the loss function includes applying the same penalty to the risky entries and the safe entries.

For some embodiments of the example method, applying the loss function includes: applying a first penalty to the safe entries, wherein the first penalty is zero; and applying a second penalty to the risky entries, wherein the first penalty is different than the second penalty.

For some embodiments of the example method, applying the loss function includes applying a penalty only to the risky entries.

For some embodiments of the example method, applying the loss function to the risky and safe entries includes applying a penalty to each of the risky entries based on how close the respective risky entry is to the corresponding quantization boundary.

For some embodiments of the example method, applying the loss function to the risky and safe entries includes applying a penalty to each of the risky entries based on a square of a distance between a predicted value corresponding to the respective risky entry and a center of a respective quantization bin.

For some embodiments of the example method, applying the loss function includes assigning a penalty to the entries based on an exponential of a distance between a predicted value for the entry and a center of a corresponding quantization bin center.

For some embodiments of the example method, the maximum tolerable error is set at run-time.

Some embodiments of the example method may further include: receiving a bitstream; and performing an arithmetic decode (AE) of the bitstream, wherein an AE output of the arithmetic decode is a reconstructed point cloud.

Some embodiments of the example method may further include obtaining a safeguard bitstream.

For some embodiments of the example method, quantizing the output includes performing a non-uniform quantization on the output.

An example apparatus in accordance with some embodiments may include: a processor; and a memory storing instructions operative, when executed by the processor, to cause the apparatus to: obtain an output of an occupancy probability estimation process; obtain a quantization step size and a maximum tolerable error; quantize the output according to the quantization step size; identify risky and safe entries of the output; and apply a loss function to the risky and safe entries.

One or more embodiments provide a computer program including instructions which when executed by one or more processors cause such processors to perform the encoding and/or decoding methods according to any of the embodiments described above. One or more embodiments also provide a computer readable storage medium having stored thereon instructions for encoding or decoding video data according to the methods described above.

One or more embodiments provide a computer readable storage medium having stored thereon video data generated according to the methods described above. One or more embodiments also provide a method and apparatus for transmitting or receiving video data generated according to the methods described above.

The embodiments described herein may be implemented in, for example, a method or a process, an apparatus, a software program, a data stream, or a signal. Even if only discussed in the context of a single form of implementation (e.g., as a method), the implementation of such features may also be implemented in other forms. An apparatus may be implemented in, for example, appropriate hardware, software, and firmware.

Corresponding methods may be implemented in, for example, a processor.

Various numeric values are used in the present application. Such specific values are for example purposes and the embodiments described are not limited to these specific values.

Various methods are described herein, and such methods include one or more steps or actions for achieving the described method. Unless a specific order of steps or actions is required for the proper operation of the method, the order and/or use of specific steps and/or actions may be modified or combined. Additionally, terms such as “first”, “second”, etc. may be used in various embodiments to modify an element, component, step, operation, etc., for example, a“first decoding” and a “second decoding”. Use of such terms does not imply an order to the operations unless specifically required.

The present application may refer to “determining” various pieces of information. Determining information may include one or more of, for example, estimating, calculating, predicting, or retrieving (e.g., from memory) the information.

The present application may refer to “accessing” various pieces of information. Accessing information may include one or more of, for example, receiving, retrieving (e.g., from memory), storing, moving, copying, calculating, determining, predicting, or estimating the information. Similarly, the present application may refer to “receiving” various pieces of information. Receiving information may include one or more of, for example, accessing or retrieving (e.g., from memory) the information.

It is to be understood that use of any of the following “/”, “and/or”, and “at least one of” is intended to encompass all possible selections of listed items, taken either individually or in any combination thereof.

While specific embodiments have been described in the foregoing description in connection with the accompanying drawings, it should be understood that embodiments described herein are examples only and should not be taken as limiting the scope of the present application or the following claims. Although features and elements are described herein in particular combinations, those of ordinary skill in the art will appreciate that such features or elements may be used alone or in any combination with the other features and elements. It is understood, therefore, that the overall teachings of the present application are not limited to the particular embodiments, implementations, and examples disclosed herein, but are intended to cover variations, modifications, and alternatives as defined by the appended claims and any and all equivalents thereof.

This application describes a variety of aspects, including tools, features, embodiments, models, approaches, etc. Many of these aspects are described with specificity and, at least to show the individual characteristics, are often described in a manner that may sound limiting. However, this is for purposes of clarity in description, and does not limit the application or scope of those aspects. Indeed, all of the different aspects can be combined and interchanged to provide further aspects. Moreover, the aspects can be combined and interchanged with aspects described in earlier filings as well.

Various numeric values may be used in the present application, for example. The specific values are for example purposes and the aspects described are not limited to these specific values.

Embodiments described herein may be carried out by computer software implemented by a processor or other hardware, or by a combination of hardware and software. As a non-limiting example, the embodiments can be implemented by one or more integrated circuits. The processor can be of any type appropriate to the technical environment and can encompass one or more of microprocessors, general purpose computers, special purpose computers, and processors based on a multi-core architecture, as non-limiting examples.

When a figure is presented as a flow diagram, it should be understood that it also provides a block diagram of a corresponding apparatus. Similarly, when a figure is presented as a block diagram, it should be understood that it also provides a flow diagram of a corresponding method/process.

The implementations and aspects described herein can be implemented in, for example, a method or a process, an apparatus, a software program, a data stream, or a signal. Even if only discussed in the context of a single form of implementation (for example, discussed only as a method), the implementation of features discussed can also be implemented in other forms (for example, an apparatus or program). An apparatus can be implemented in, for example, appropriate hardware, software, and firmware. The methods can be implemented in, for example, a processor, which refers to processing devices in general, including, for example, a computer, a microprocessor, an integrated circuit, or a programmable logic device. Processors also include communication devices, such as, for example, computers, cell phones, portable/personal digital assistants (“PDAs”), and other devices that facilitate communication of information between end-users.

Reference to “one embodiment” or “an embodiment” or “one implementation” or “an implementation”, as well as other variations thereof, means that a particular feature, structure, characteristic, and so forth described in connection with the embodiment is included in at least one embodiment. Thus, the appearances of the phrase “in one embodiment” or “in an embodiment” or “in one implementation” or “in an implementation”, as well any other variations, appearing in various places throughout this application are not necessarily all referring to the same embodiment.

Additionally, this application may refer to “determining” various pieces of information. Determining the information can include one or more of, for example, estimating the information, calculating the information, predicting the information, or retrieving the information from memory.

Further, this application may refer to “accessing” various pieces of information. Accessing the information can include one or more of, for example, receiving the information, retrieving the information (for example, from memory), storing the information, moving the information, copying the information, calculating the information, determining the information, predicting the information, or estimating the information.

Additionally, this application may refer to “receiving” various pieces of information. Receiving is, as with “accessing”, intended to be a broad term. Receiving the information can include one or more of, for example, accessing the information, or retrieving the information (for example, from memory). Further, “receiving” is typically involved, in one way or another, during operations such as, for example, storing the information, processing the information, transmitting the information, moving the information, copying the information, erasing the information, calculating the information, determining the information, predicting the information, or estimating the information.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended for as many items as are listed.

Implementations can produce a variety of signals formatted to carry information that can be, for example, stored or transmitted. The information can include, for example, instructions for performing a method, or data produced by one of the described implementations. For example, a signal can be formatted to carry the bitstream of a described embodiment. Such a signal can be formatted, for example, as an electromagnetic wave (for example, using a radio frequency portion of spectrum) or as a baseband signal. The formatting can include, for example, encoding a data stream and modulating a carrier with the encoded data stream. The information that the signal carries can be, for example, analog or digital information. The signal can be transmitted over a variety of different wired or wireless links, as is known. The signal can be stored on a processor-readable medium.

Note that various hardware elements of one or more of the described embodiments are referred to as “modules” that carry out (i.e., perform, execute, and the like) various functions that are described herein in connection with the respective modules. As used herein, a module includes hardware (e.g., one or more processors, one or more microprocessors, one or more microcontrollers, one or more microchips, one or more application-specific integrated circuits (ASICs), one or more field programmable gate arrays (FPGAs), one or more memory devices) deemed suitable by those of skill in the relevant art for a given implementation. Each described module may also include instructions executable for carrying out the one or more functions described as being carried out by the respective module, and it is noted that those instructions could take the form of or include hardware (i.e., hardwired) instructions, firmware instructions, software instructions, and/or the like, and may be stored in any suitable non-transitory computer-readable medium or media, such as commonly referred to as RAM, ROM, etc.

Although features and elements are described above in particular combinations, one of ordinary skill in the art will appreciate that each feature or element can be used alone or in any combination with the other features and elements. In addition, the methods described herein may be implemented in a computer program, software, or firmware incorporated in a computer-readable medium for execution by a computer or processor. Examples of computer-readable storage media include, but are not limited to, a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs). A processor in association with software may be used to implement a radio frequency transceiver for use in a WTRU, UE, terminal, base station, RNC, or any host computer.

1. A method comprising:
obtaining an output of an occupancy probability estimation process;
obtaining a quantization step size and a maximum tolerable error;
quantizing the output according to the quantization step size;
identifying risky and safe entries of the output; and
applying a loss function to the risky and safe entries.

2. The method of claim 1, further comprising training the occupancy probability estimation process.

3. The method of claim 2,
wherein the training is done from scratch, and
wherein scratch is a neutral starting point.

4. The method of claim 2,
wherein the occupancy probability estimation process was previously trained, and
wherein training the occupancy probability estimation process comprises finetuning weights of the already-trained occupancy probability estimation process.

5. The method of claim 1, wherein identifying the risky and safe entries comprises:
determining quantization boundaries from the quantization step assuming uniform quantization;
determining a distance between an entry and a respective closest quantization boundary of the entry; and
indicating whether the entry falls within a threshold distance of the respective closest quantization boundary.

6. The method of claim 5,
wherein the threshold distance is ceₘₐₓ,
wherein eₘₐₓ is the maximum tolerable error,
wherein c is a constant, and
wherein c is greater than or equal to 1.

7. The method of claim 6, wherein identifying the risky and safe entries further comprises:
identifying the risky entries as entries in which the distance is less than or equal to the value ceₘₐₓ; and
identifying the safe entries as entries in which the distance is greater than the value ceₘₐₓ.

8. The method of claim 5, wherein identifying risky and safe entries comprises:
indicating the risky entries as entries inside a range around their respective quantization boundaries; and
indicating the safe entries as entries outside the range around their respective quantization boundaries.

9. The method of claim 1, further comprising:
obtaining a safeguard bitstream; and
extracting the quantization boundaries from the safeguard bitstream.

10. The method of claim 1, wherein applying the loss function comprises applying the same penalty to the risky entries and the safe entries.

11. The method of claim 1, wherein applying the loss function comprises:
applying a first penalty to the safe entries,
wherein the first penalty is zero; and
applying a second penalty to the risky entries,
wherein the first penalty is different than the second penalty.

12. The method of claim 1, wherein applying the loss function comprises applying a penalty only to the risky entries.

13. The method of claim 1, wherein applying the loss function to the risky and safe entries comprises applying a penalty to each of the risky entries based on how close the respective risky entry is to the corresponding quantization boundary.

14. The method of claim 1, wherein applying the loss function to the risky and safe entries comprises applying a penalty to each of the risky entries based on a square of a distance between a predicted value corresponding to the respective risky entry and a center of a respective quantization bin.

15. The method of claim 1, wherein applying the loss function comprises assigning a penalty to the entries based on an exponential of a distance between a predicted value for the entry and a center of a corresponding quantization bin center.

16. The method of claim 1, wherein the maximum tolerable error is set at run-time.

17. The method of claim 1, further comprising:
receiving a bitstream; and
performing an arithmetic decode (AE) of the bitstream,
wherein an AE output of the arithmetic decode is a reconstructed point cloud.

18. The method of claim 1, further comprising obtaining a safeguard bitstream.

19. The method of claim 1, wherein quantizing the output comprises performing a non-uniform quantization on the output.

20. An apparatus comprising:
a processor; and
a memory storing instructions operative, when executed by the processor, to cause the apparatus to:
obtain an output of an occupancy probability estimation process;
obtain a quantization step size and a maximum tolerable error;
quantize the output according to the quantization step size;
identify risky and safe entries of the output; and
apply a loss function to the risky and safe entries.
